(19) United States
(12) Patent Application Publication
(10) Pub. No.: US 2013/0286598 A1
(43) Pub. Date: Oct. 31, 2013

(54) ELECTRICAL APPARATUS AND METHOD FOR PRODUCING ELECTRICAL APPARATUS

(71) Applicant: SUMITOMO ELECTRIC INDUSTRIES, LTD., Osaka (JP)

(72) Inventor: Yuki ADA, Osaka (JP)

(21) Appl. No.: 13/927,645

(22) Filed: Jun. 26, 2013

Related U.S. Application Data
(63) Continuation of application No. PCT/JP2011/068527, filed on Aug. 15, 2011.

(30) Foreign Application Priority Data
Dec. 28, 2010 (JP) 2010-293484

(51) Int. Cl. H05K 1/02; H05K 3/00

(52) U.S. Cl. CPC H05K 1/0203; H05K 3/00
USPC 361/720; 29/831

(57) ABSTRACT

Regarding an electrical apparatus, in an opposing part facing a board, the opposing part being on a surface of in a heat dissipator, a contact part which is brought into contact with a first region of a second main surface corresponding to an electrical component and a surrounding region of the electrical component and which is brought into contact with a second region of the second main surface corresponding to a fixing member and a surrounding region of the fixing member protrudes relative to a portion of the opposing part other than the contact part. The degree of flatness of a contact surface, in the contact part, that is brought into contact with the first region and the second region is higher than the degree of flatness of a surface of the opposing part other than the contact surface.

### TECHNICAL FIELD

The present invention relates to an electrical apparatus and a method for producing the electrical apparatus, and in particular, to an electrical apparatus provided with a heat dissipator, and a method for producing the electrical apparatus.

### BACKGROUND ART

As an example for heat dissipation measures for electrical apparatuses, Japanese Laid-Open Patent Publication No. H11-195889 (Patent Literature 1) discloses the following technology, for example. That is, a printed circuit board heat dissipation component is attached to a printed circuit board for dissipating heat generated in an electronic component mounted on the printed circuit board, and the heat dissipation component includes: an attachment part which is inserted in a lead inserting hole of the printed circuit board and soldered on the printed circuit board together with a lead of the electronic component; and a heat dissipation part rising from the board surface as an integral body with the attachment part.

### CITATION LIST

### Patent Literature

[PTL 1] Japanese Laid-Open Patent Publication No. H11-195889

### SUMMARY OF THE INVENTION

### Problems to be Solved by the Invention

Here, a structure for mounting a power device is considered. Since a power device generates heat to a great extent, the following structure is conceivable, for example, in which: a board having a power device mounted thereon and a heat dissipator are brought into contact with each other, and the board and the heat dissipator are fixed together with a screw, to dissipate heat.

However, in such a mounting structure, when the evenness of the heat dissipator is low, the portions where the board and the heat dissipator are brought into contact with each other are reduced, and thus, a sufficient heat dissipation effect is not obtained. On the other hand, the greater the area of the heat dissipator having an increased evenness is, the greater the surface working costs become.

Patent Literature 1 does not disclose a structure for solving such a problem.

The present invention is made in order to solve the above problem. An object of the present invention is to provide an electrical apparatus and a method for producing the electrical apparatus that can improve the heat dissipation performance and can prevent increase of production costs.

### Solution to the Problems

(1) In order to solve the above problem, an electrical apparatus according to an aspect of this invention is an electrical apparatus including: a board which includes a first main surface and a second main surface and in which an electrical component is attached to the first main surface; a heat dissipator; and a fixing member which fixes the second main surface of the board and the heat dissipator together in such a manner as to be in contact with each other, by passing through the board from the first main surface to the second main surface to be inserted in the heat dissipator, wherein in an opposing part facing the board, the opposing part being on a surface of the heat dissipator, a contact part which is brought into contact with a first region of the second main surface corresponding to the electrical component and a surrounding region of the electrical component and which is brought into contact with a second region of the second main surface corresponding to the fixing member and a surrounding region of the fixing member protrudes relative to a portion of the opposing part other than the contact part, and the degree of flatness of a contact surface, in the contact part, that is brought into contact with the first region and the second region is higher than the degree of flatness of a surface of the opposing part other than the contact surface.

With this structure, it is possible to realize both low surface working costs and a high heat dissipation effect. That is, it is possible to minimize the area having an increased degree of flatness, and to obtain a sufficient heat dissipation effect. Therefore, it is possible to improve the heat dissipation performance and to prevent increase of production costs. Further, by bringing the heat dissipator, and the portion of the board corresponding to the electrical component and its surrounding region and the portion of the board corresponding to the fixing member and its surrounding region into contact with each other, compared with a structure where one of the above two portions is brought into contact with the heat dissipator, the heat dissipation performance can be improved.

(2) Further, the electrical apparatus according to another aspect of this invention is an electrical apparatus including: a board which includes a first main surface and a second main surface and to which an electrical component is attached; a heat dissipator, and a fixing member which fixes the board and the heat dissipator together by passing through the board from the first main surface to the second main surface to be inserted in the heat dissipator, wherein the electrical component projects from the second main surface of the board, and is in contact with the heat dissipator at a tip of a projecting portion of the electrical component or in contact with the heat dissipator via a first heat dissipation member provided between the electrical component and the heat dissipator, and on the surface of the heat dissipator, the degree of flatness of a contact surface that is brought into contact with the electrical component or the first heat dissipation member is higher than the degree of flatness of a surface of an opposing part other than the contact surface, the opposing part facing the board.

With this structure, it is possible to realize both low surface working costs and a high heat dissipation effect. That is, it is possible to minimize the area having an increased degree of flatness, and to obtain a sufficient heat dissipation effect. Therefore, it is possible to improve the heat dissipation performance and to prevent increase of production costs. Further, on the surface of the heat dissipator, it is sufficient to increase the degree of flatness only of the portion corresponding to the electrical component or the first heat dissipation member. Thus, surface working costs can be reduced. Further, since heat from the electrical component is conveyed to the heat dissipator directly or via the first heat dissipation member, the necessity for a structure that promotes heat conduction from the fixing member to the heat dissipator is reduced.

(3) Preferably, the fixing member reaches the heat dissipator by being inserted through a second heat dissipation member which is in close contact with the board and the heat dissipator between the board and the heat dissipator, and on the surface of the heat dissipator, the degree of flatness of the contact surface that is brought into contact with the electrical component or the first heat dissipation member and the degree of flatness of a contact surface that is brought into contact with the second heat dissipation member are higher than the degree of flatness of a surface of the opposing part other than these contact surfaces.

As described above, by providing the second heat dissipation member and by increasing the degree of flatness of the contact surface, on the surface of the heat dissipator, that is brought into contact with the second heat dissipation member, it is possible to promote heat conduction from the electrical component to the heat dissipator. Thus, the heat dissipation effect can be further enhanced.

(4) Preferably, in the opposing part, a contact part which is brought into contact with a member region of the second main surface corresponding to the fixing member and a surrounding region of the fixing member protrudes relative to a portion of the opposing part other than the contact part, and the degree of flatness of the contact surface, on the surface of the heat dissipator, that is brought into contact with the electrical component or the first heat dissipation member, and the degree of flatness of a contact surface, in the contact part, that is brought into contact with the member region are higher than the degree of flatness of a surface of the opposing part other than these contact surfaces.

With this structure, it is possible to realize both low surface working costs and a high heat dissipation effect. That is, it is possible to minimize the area having an increased degree of flatness, and to obtain a sufficient heat dissipation effect. Therefore, it is possible to improve the heat dissipation performance and to prevent increase of production costs. Further, by bringing the heat dissipator, and the portion of the board corresponding to the electrical component or the heat dissipation member and the portion of the board corresponding to the fixing member and its surrounding region, into contact with each other, compared with a structure where the heat dissipator is brought into contact with one of the portion of the board corresponding to the electrical component or the heat dissipation member and the portion of the board corresponding to the fixing member and its surrounding region, the heat dissipation performance can be improved.

(5) Further, the electrical apparatus according to still another aspect of this invention is an electrical apparatus including: a board which includes a first main surface and a second main surface and in which an electrical component is attached to the first main surface; a heat dissipator; and a fixing member which fixes the second main surface of the board and the heat dissipator together in such a manner as to be in contact with each other, by passing through the board from the first main surface to the second main surface to be inserted in the heat dissipator, wherein in an opposing part facing the board , the opposing part being on a surface of the heat dissipator, a contact part which is brought into contact with a component region of the second main surface corresponding to the electrical component and a surrounding region of the electrical component protrudes relative to a portion of the opposing part other than the contact part, and the fixing member reaches the heat dissipator by being inserted through a heat dissipation member which is in close contact with the board and the heat dissipator between the board and the heat dissipator, and the degree of flatness of a contact surface, in the contact part, that is brought into contact with the component region, and the degree of flatness of contact surface, in the heat dissipator, that is brought into contact with the heat dissipation member are higher than the degree of flatness of a surface of the opposing part other than these contact surfaces.

With this structure, it is possible to realize both low surface working costs and a high heat dissipation effect. That is, by increasing the degree of flatness of the protruding contact part, the degree of contact between the board and the heat dissipator is increased in the portion where the heat dissipation effect is especially enhanced. Further, by providing the heat dissipation member and by increasing the degree of flatness of the contact surface, in the heat dissipator, that is brought into contact with the heat dissipation member, heat conduction from the electrical component to the heat dissipator can be promoted. Thus, the heat dissipation effect can be enhanced. Accordingly, it is possible to minimize the area having an increased degree of flatness, and to obtain a sufficient heat dissipation effect. Therefore, it is possible to improve the heat dissipation performance and to prevent increase of production costs.

(6) Preferably, the electrical component is attached to a vicinity of the fixing member.

With this structure, it is possible to arrange the electrical component in a region having a high degree of contact with the heat dissipator, and heat generated from the electrical component can be conducted to the heat dissipator via the fixing member. Thus, the heat dissipation effect can further be enhanced.

(7) Preferably, the electrical apparatus is a radio communication device which includes an amplifier for amplifying a radio signal, as the electrical component.

With this structure, it is possible to appropriately take heat dissipation measures for the amplifier whose temperature is especially increased in the radio communication device.

(8) In order to solve the above mentioned problem, a method for producing an electrical apparatus according to an aspect of this invention is a method for producing an electrical apparatus, the method including: a step of preparing a board which includes a first main surface and a second main surface and in which an electrical component is attached to the first main surface, and a fixing member to be passed through the board from the first main surface to the second main surface; a step of casting a heat dissipator in which, in an opposing part facing the board, the opposing part being on a surface of the heat dissipator, a contact part which is brought into contact with a first region of the second main surface corresponding to the electrical component and a surrounding region of the electrical component and which is brought into contact with a second region of the second main surface corresponding to the fixing member and a surrounding region of the fixing member protrudes relative to a portion of the opposing part other than the contact part; a step of working the heat dissipator such that the degree of flatness of a contact surface, in the contact part, that is brought into contact with the first region and the second region is higher than the degree of flatness of a surface of the opposing part other than the contact surface; and a step of fixing the second main surface of the board and the heat dissipator together in such a manner as to be in contact with each other, by passing the fixing member through the board from the first main surface to the second main surface to be inserted in the heat dissipator.

With this structure, it is possible to realize both low surface working costs and a high heat dissipation effect. That is, it is possible to minimize the area having an increased degree of flatness, and to obtain a sufficient heat dissipation effect. Therefore, it is possible to improve the heat dissipation performance and to prevent increase of production costs. Further, in the board, by bring the heat dissipator, and the portion corresponding to the electrical component and its surrounding region and the portion corresponding to the fixing member and its surrounding region, into contact with each other, compared with a structure where one of the above two portions are brought into contact with the heat dissipator, the heat dissipation performance can be improved.

(9) Further, a method for producing an electrical apparatus according to another aspect of this invention is a method for producing an electrical apparatus, the method including: a step of preparing a board which includes a first main surface and a second main surface and to which an electrical component is attached, and a fixing member to be passed through the board from the first main surface to the second main surface; a step of causing the electrical component to project from the second main surface of the board to be brought into contact with a heat dissipator at a tip of a projecting portion of the electrical component, or bringing the electrical component into contact with the heat dissipator via a heat dissipation member provided between the electrical component and the heat dissipator; a step of fixing the second main surface of the board and the electrical component, and the heat dissipator together, by passing the fixing member through the board from the first main surface to the second main surface to be inserted in the heat dissipator; and a step of working, before the step of bringing the electrical component into contact and the step of fixing the electrical component using the fixing member, the heat dissipator such that, in an opposing part facing the board, the opposing part being on a surface of the heat dissipator, the degree of flatness of a contact surface that is brought into contact with the electrical component or the heat dissipation member is higher than the degree of flatness of a surface of the opposing part other than the contact surface.

With this structure, it is possible to realize both low surface working costs and a high heat dissipation effect. That is, it is possible to minimize the area having an increased degree of flatness, and to obtain a sufficient heat dissipation effect. Therefore, it is possible to improve the heat dissipation performance and to prevent increase of production costs. Further, on the surface of the heat dissipator, it is sufficient to increase the degree of flatness only of the portion corresponding to the electrical component or the heat dissipation member. Thus, surface working costs can be reduced. Further, since heat from the electrical component is conveyed to the heat dissipator directly or via the heat dissipation member, the necessity for a structure that promotes heat conduction from the fixing member to the heat dissipator is reduced.

### BRIEF DESCRIPTION OF THE DRAWINGS

FIG. 1 shows a structure of an electrical apparatus according to a first embodiment.

[Fig. 2] FIG. 2 is a functional block diagram of a remote radio head according to the first embodiment.

FIG. 3 shows a mounting structure of a comparative example of the electrical apparatus according to the first embodiment.

FIG. 4 is a perspective view showing a mounting structure of the electrical apparatus according to the first embodiment.

FIG. 5 is a cross-sectional view showing the mounting structure of the electrical apparatus according to the first embodiment.

FIG. 6 is a flow chart defining the procedure for producing the electrical apparatus according to the first embodiment.

FIG. 7 is a cross-sectional view showing a method for working a surface of a heat dissipator in comparative example 1 of the electrical apparatus according to the first embodiment.

FIG. 8 is a cross-sectional view showing a method for working a surface of the heat dissipator in comparative example 2 of the electrical apparatus according to the first embodiment.

FIG. 9 is a cross-sectional view showing a method for working a surface of a heat dissipator in the electrical apparatus according to the first embodiment of the present invention.

FIG. 10 is a cross-sectional view showing a mounting structure of a modification of the electrical apparatus according to the first embodiment of the present invention.

FIG. 11 is a cross-sectional view showing a mounting structure of an electrical apparatus according to a second embodiment of the present invention.

FIG. 12 is a flow chart defining the procedure for producing the electrical apparatus according to the second embodiment of the present invention.

FIG. 13 is a cross-sectional view showing a mounting structure of a modification of the electrical apparatus according to the second embodiment of the present invention.

FIG. 14 is a cross-sectional view showing a mounting structure of an electrical apparatus according to a third embodiment of the present invention.

FIG. 15 is a flow chart defining the procedure for producing the electrical apparatus according to the third embodiment of the present invention.

FIG. 16 is a cross-sectional view showing a mounting structure of an electrical apparatus according to a fourth embodiment of the present invention.

FIG. 17 is a flow chart defining the procedure for producing the electrical apparatus according to the fourth embodiment of the present invention.

### DESCRIPTION OF EMBODIMENTS

Hereinafter, embodiments of the present invention will be described with reference to the drawings. Note that, in the drawings, the same or corresponding parts are denoted by the same reference characters, and description thereof is not repeated.

### First Embodiment

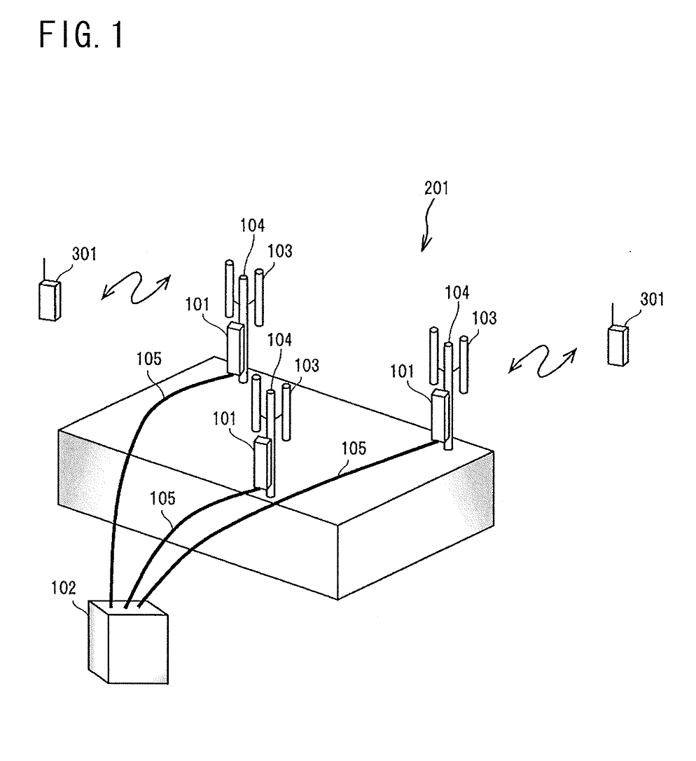

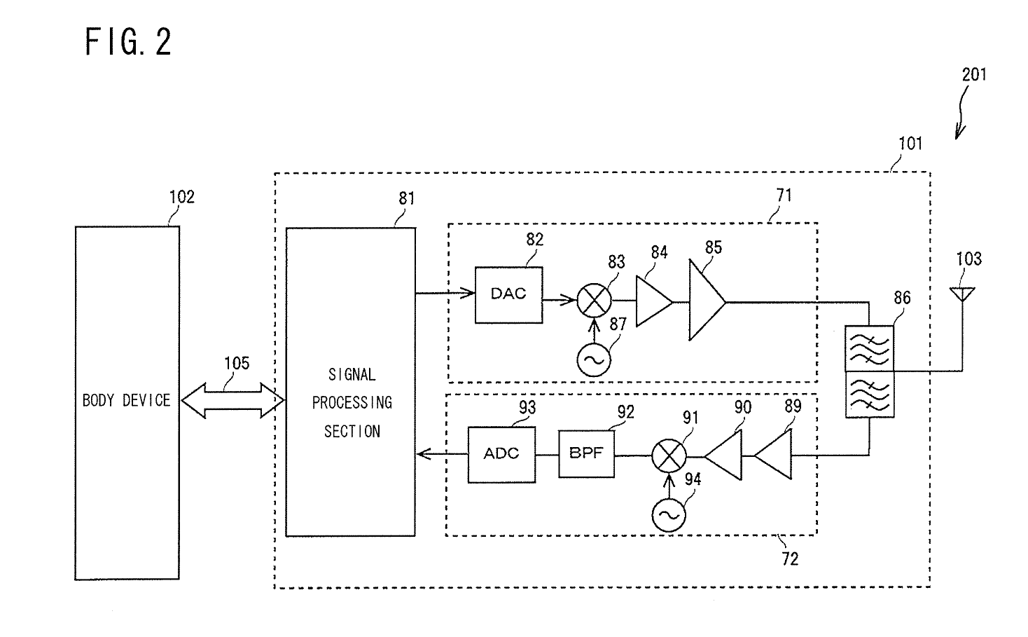

FIG. 1 shows a structure of an electrical apparatus according to a first embodiment of the present invention.

With reference to FIG. 1, an electrical apparatus 201 is a radio communication device, for example, and includes one or a plurality of remote radio heads (RRH) 101, and a body device 102.

Each remote radio head 101 is a device obtained by separating a part that performs transmission and reception of radio signals, from a radio base station device used in mobile communication. The remote radio head 101 is attached to an antenna pole 104 installed on the roof of a building or the like. Further, an antenna 103 is attached to the antenna pole 104.

The remote radio head 101 converts a radio signal received from a radio terminal device 301 via the antenna 103 into a digital signal, and outputs the digital signal to the body device 102 via an optical fiber 105. Further, the remote radio head 101 converts a digital signal received from the body device 102 via the optical fiber 105 into a radio signal, and transmits the radio signal to the radio terminal device 301 via the antenna 103.

FIG. 2 is a functional block diagram of a remote radio head according to the first embodiment of the present invention.

With reference to FIG. 2, the remote radio head 101 includes a signal processing section 81, a radio transmission section 71, a radio reception section 72, and a transmission and reception filter 86. The radio transmission section 71 includes a digital/analog converter (DAC) 82, a modulator 83, a driver amplifier 84, a power amplifier 85, and an oscillator 87. The radio reception section 72 includes reception amplifiers 89 and 90, a mixer 91, a BPF (Band Pass Filter) 92, an analog/digital converter (ADC) 93, and an oscillator 94. The signal processing section 81 is a DSP (Digital Signal Processor), for example.

The signal processing section 81 performs signal processing on a digital signal received from the body device 102 via the optical fiber 105, and outputs the resultant signal to the radio transmission section 71.

The radio transmission section 71 converts the digital signal received from the signal processing section 81 into an analog signal, converts the converted analog signal into a radio signal, that is, a signal in an RF (Radio Frequency) band, and transmits the radio signal to the radio terminal device 301.

The radio reception section 72 receives a radio signal from the radio terminal device 301, converts the radio signal into an IF (Intermediate Frequency) signal, converts the converted IF signal into a digital signal, and outputs the digital signal to the signal processing section 81.

The signal processing section 81 performs various types of signal processing on the digital signal received from the radio reception section 72, and outputs the resultant signal to the body device 102 via the optical fiber 105.

More specifically, the signal processing section 81 outputs a digital signal received from the body device 102 to the digital/analog converter 82.

The digital/analog converter 82 converts the digital signal received from the signal processing section 81 into an analog signal, and outputs the analog signal to the modulator 83.

The oscillator 87 generates a locally generated signal and outputs this signal to the modulator 83. The modulator 83 multiples the analog signal in a baseband received from the digital/analog converter 82 by the locally generated signal received from the oscillator 87, thereby performing, for example, a quadrature modulation on the analog signal received from the digital/analog converter 82 to be converted into a radio signal, and outputs the radio signal to the driver amplifier 84.

The driver amplifier 84 amplifies the radio signal received from the modulator 83, and outputs the resultant signal to the power amplifier 85.

The power amplifier 85 further amplifies the radio signal received from the driver amplifier 84. The radio signal amplified by the power amplifier 85 is transmitted, via the transmission and reception filter 86 and the antenna 103, to the radio terminal device 301.

The transmission and reception filter 86 removes an unwanted signal from the radio signal received from the power amplifier 85, and outputs the resultant signal to the antenna 103. Further, the transmission and reception filter 86 removes noise from a radio signal received from the antenna 103, and outputs the resultant signal to the reception amplifier 89. The transmission and reception filter 86 is a band-pass filter, for example, and outputs a signal obtained by attenuating, from among frequency components of the received radio signal, components outside a predetermined frequency band.

The reception amplifier 89 is an LNA (Low Noise Amplifier), for example, and receives the radio signal from the radio terminal device 301 via the antenna 103 and the transmission and reception filter 86, amplifies the received radio signal, and outputs the resultant signal to the reception amplifier 90.

The reception amplifier 90 is an LNA, for example, and further amplifies the radio signal received from the reception amplifier 89 and outputs the resultant signal to the mixer 91.

The oscillator 94 generates a locally generated signal and outputs this signal to the mixer 91. The mixer 91 multiplies the radio signal received from the reception amplifier 90 by the locally generated signal received from the oscillator 94, thereby converting the radio signal received from the reception amplifier 90 into an IF signal, and outputting the IF signal to the band-pass filter 92.

The band-pass filter 92 outputs, to the analog/digital converter 93, a signal obtained by attenuating, from among frequency components of the IF signal received from the mixer 91, components outside a predetermined frequency band.

The analog/digital converter 93 converts the IF signal received from the band-pass filter 92 into a digital signal, and outputs the digital signal to the signal processing section 81.

The signal processing section 81 converts the digital signal in the IF band received from the analog/digital converter 93 into a digital signal in the baseband, through quadrature demodulation, for example, and outputs the digital signal to the body device 102 via the optical fiber 105.

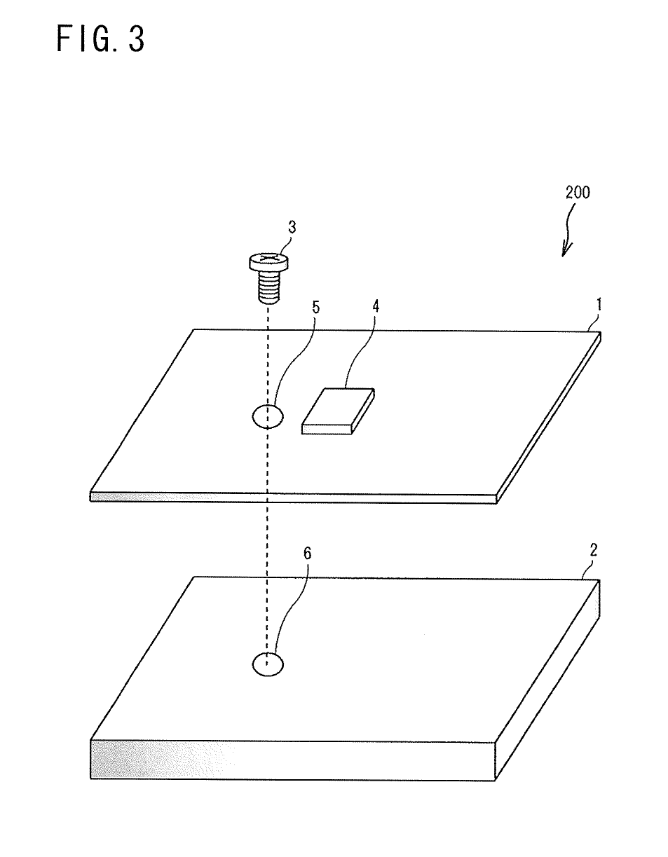

FIG. 3 shows a mounting structure of a comparative example of the electrical apparatus according to the first embodiment of the present invention.

With reference to FIG. 3, an electrical apparatus 200 includes a printed circuit board 1, a heat dissipator 2, a fixing member 3, and an electrical component 4.

The electrical component 4 is the power amplifier 85 shown in FIG. 2, for example. The fixing member 3 is a screw, for example.

The printed circuit board 1 and the heat dissipator 2 are provided with tapped holes 5 and 6, respectively. The fixing member 3 fixes the printed circuit board 1 and the heat dissipator 2 together in such a manner as to be in contact with each other, by passing through the printed circuit board 1 via the tapped hole 5 to be inserted in the tapped hole 6 in the heat dissipator 2.

Thus, in the electrical apparatus 200, heat dissipation is performed by bringing the printed circuit board 1 having the electrical component 4 mounted thereon and the heat dissipator 2 into contact with each other and by fixing them with a screw.

In this mounting structure, in a case where the evenness, i.e., the degree of flatness, of the contact surface in the heat dissipator 2 which is brought into contact with the printed circuit board 1 is low, the portions where the printed circuit board 1 and the heat dissipator 2 are brought into contact with each other are reduced. This prevents a sufficient heat dissipation effect from being obtained. On the other hand, the greater the area having an increased degree of flatness in the above contact surface is, the greater the surface working costs become.

Therefore, the electrical apparatus according to the first embodiment of the present invention solves the above problem, by adopting the following mounting structure. Hereinafter, parts that are the same as or correspond to those in FIG. 3 are denoted by the same reference characters, and description thereof is not repeated.

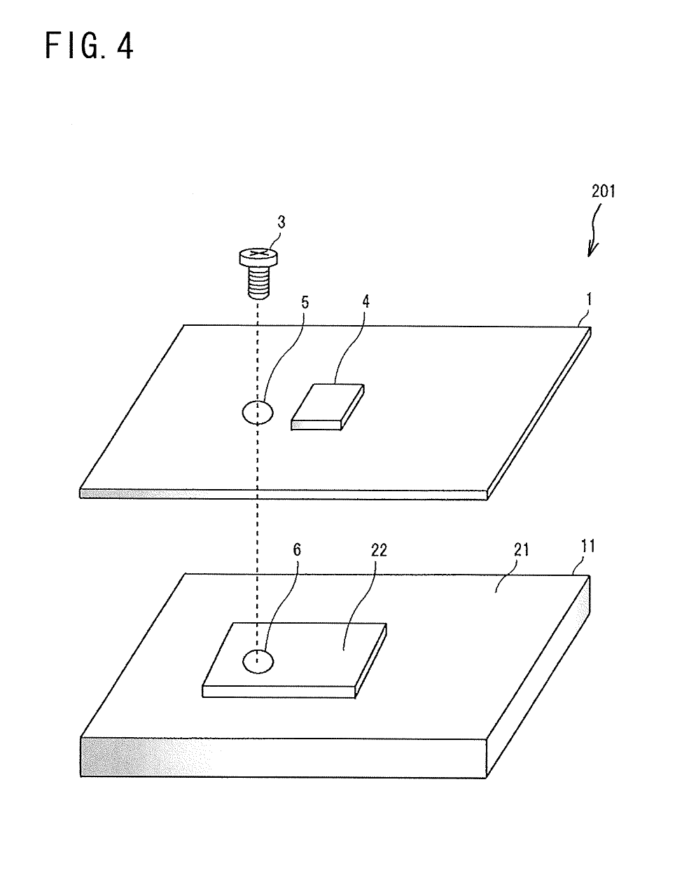

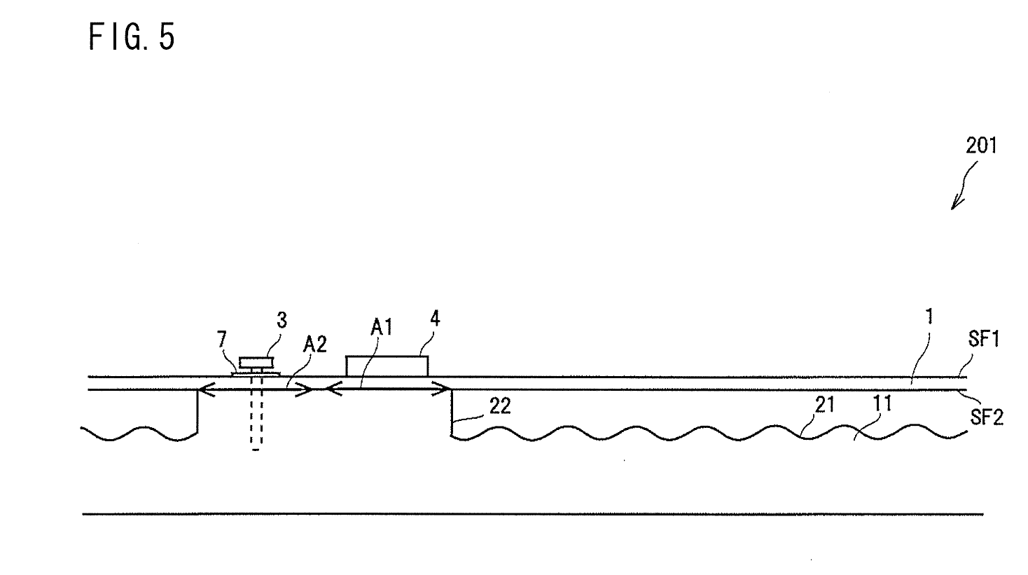

FIG. 4 is a perspective view showing a mounting structure of the electrical apparatus according to the first embodiment of the present invention. FIG. 5 is a cross-sectional view showing the mounting structure of the electrical apparatus according to the first embodiment of the present invention.

With reference to FIG. 4, the electrical apparatus 201 includes the printed circuit board 1, a heat dissipator 11, the fixing member 3, and the electrical component 4.

The printed circuit board 1 includes a main surface SF1 and a main surface SF2, and to the main surface SF1, the electrical component 4 is attached.

The fixing member 3 fixes the main surface SF2 of the printed circuit board 1 and the heat dissipator 11 together in such a manner as to be in contact with each other, by passing through the printed circuit board 1 from the main surface SF1 to the main surface SF2 to be inserted in the heat dissipator 11.

In an opposing part 21 facing the printed circuit board 1, the opposing part 21 being on a surface of the heat dissipator 11, a contact part 22, which is brought into contact with a component region A1 of the main surface SF2 corresponding to the electrical component 4 and its surrounding region and which is brought into contact with a screw region A2 of the main surface SF2 corresponding to the fixing member 3 and its surrounding region, protrudes relative to the portion of the opposing part 21 other than the contact part 22. The screw region A2 is a region corresponding to the fixing member 3 being a screw and a washer 7, for example.

The degree of flatness of the contact surface, in the contact part 22, that is brought into contact with the component region A1 and the screw region A2 is higher than the degree of flatness of the surface of the opposing part 21 other than the contact surface.

Further, in the vicinity of the tapped hole 5 and the tapped hole 6, the degree of contact between the printed circuit board 1 and the heat dissipator 11 is highest. Further, the fixing member 3 itself promotes heat conduction from the printed circuit board 1 to the heat dissipator 11. Accordingly, in the vicinity of the tapped hole 5 and the tapped hole 6, the heat dissipation effect is significantly enhanced.

In the electrical apparatus 201, the electrical component 4 is attached in the vicinity of the fixing member 3. That is, in the electrical apparatus 201, a tapped hole is provided in the vicinity of the electrical component 4, in addition to portions where tapped holes are structurally needed. With this structure, the heat dissipation effect can further be enhanced.

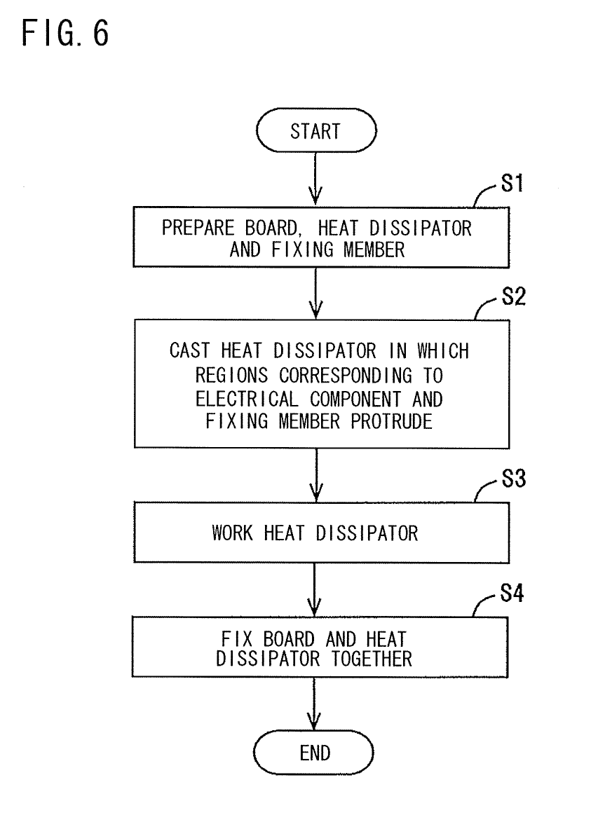

FIG. 6 is a flow chart defining the procedure for producing the electrical apparatus according to the first embodiment of the present invention.

With reference to FIG. 6, first, the printed circuit board 1 which includes the main surface SF1 and the main surface SF2 and in which the electrical component 4 is attached to the main surface SF1 is prepared. Further, the fixing member 3 to be passed through the printed circuit board 1 from the main surface SF1 to the main surface SF2 is prepared (step S1).

Next, the heat dissipator 11 is cast in which, in the opposing part 21 facing the printed circuit board 1, the contact part 22, which is brought into contact with the component region A1 of the main surface SF2 corresponding to the electrical component 4 and its surrounding region and which is brought into contact with the screw region A2 of the main surface SF2 corresponding to the fixing member 3 and its surrounding region, protrudes relative to the portion of the opposing part 21 other than the contact part 22 (step S2).

Next, the heat dissipator 11 is worked such that the degree of flatness of the contact surface, in the contact part 22, that is brought into contact with the component region A 1 and the screw region A2 becomes higher than the degree of flatness of the surface of the opposing part 21 other than the contact surface (step S3).

Next, by passing the fixing member 3 through the printed circuit board 1 from the main surface SF1 to the main surface SF2 to be inserted in the heat dissipator 11, the main surface SF2 of the printed circuit board 1 and the heat dissipator 11 are fixed together in such a manner as to be in contact with each other (step S4).

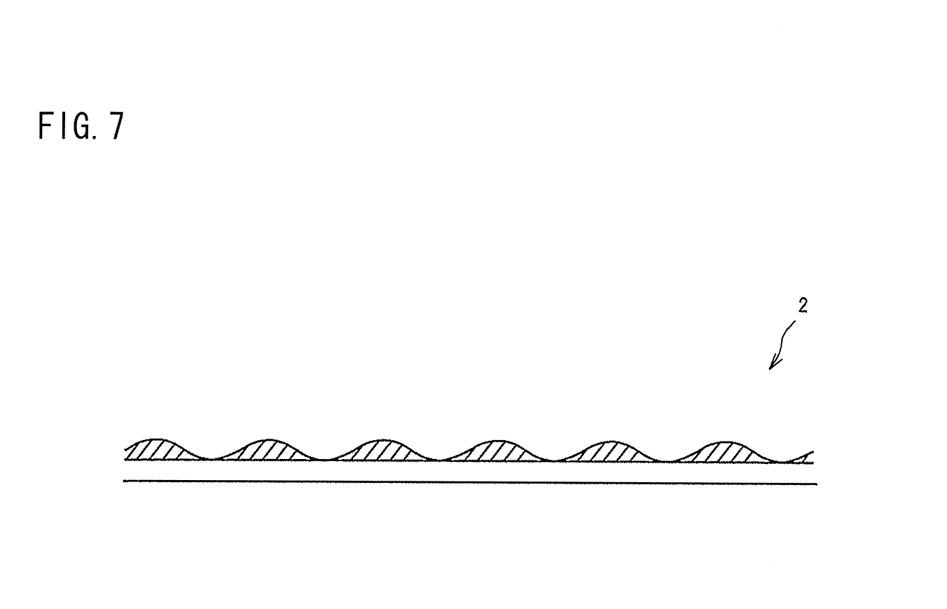

FIG. 7 is a cross-sectional view showing a method for working a surface of a heat dissipator in comparative example 1 of the electrical apparatus according to the first embodiment of the present invention.

With reference to FIG. 7, in order to improve the heat dissipation performance in the electrical apparatus 200, it is conceivable to perform surface working on the entirety of the opposing part 21. However, such a method will increase surface working costs.

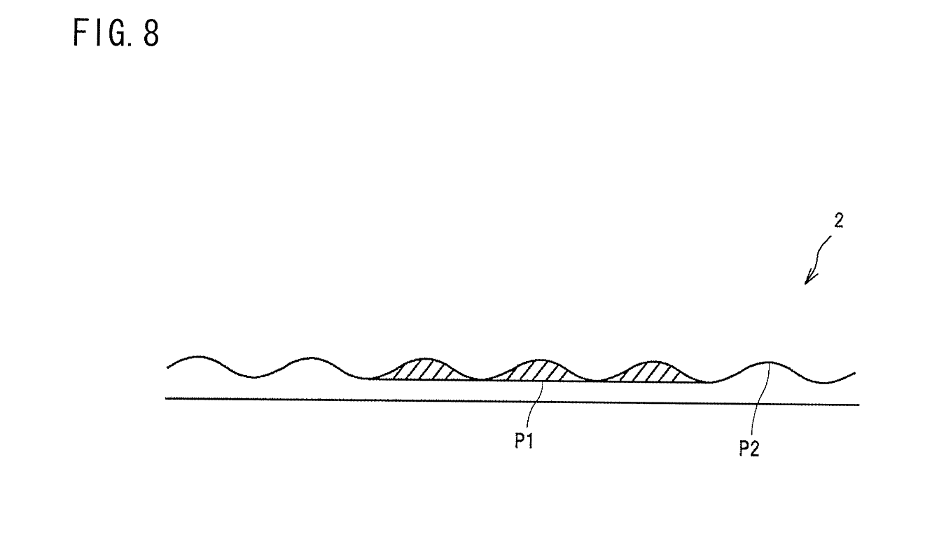

FIG. 8 is a cross-sectional view showing a method for working a surface of the heat dissipator in comparative example 2 of the electrical apparatus according to the first embodiment of the present invention.

With reference to FIG. 8, in order to reduce working costs for the electrical apparatus 200, it is conceivable to perform surface working, in the heat dissipator 2, on only a portion that corresponds to the electrical component 4 or the fixing member 3. However, the level of a portion P1 where such surface working has been performed becomes lower than the level of the surrounding portion P2, which is the portion of the heat dissipator 2 other than the portion P1. Thus, in the portion P1, bringing the heat dissipator 2 and the printed circuit board 1 into contact with each other becomes difficult itself.

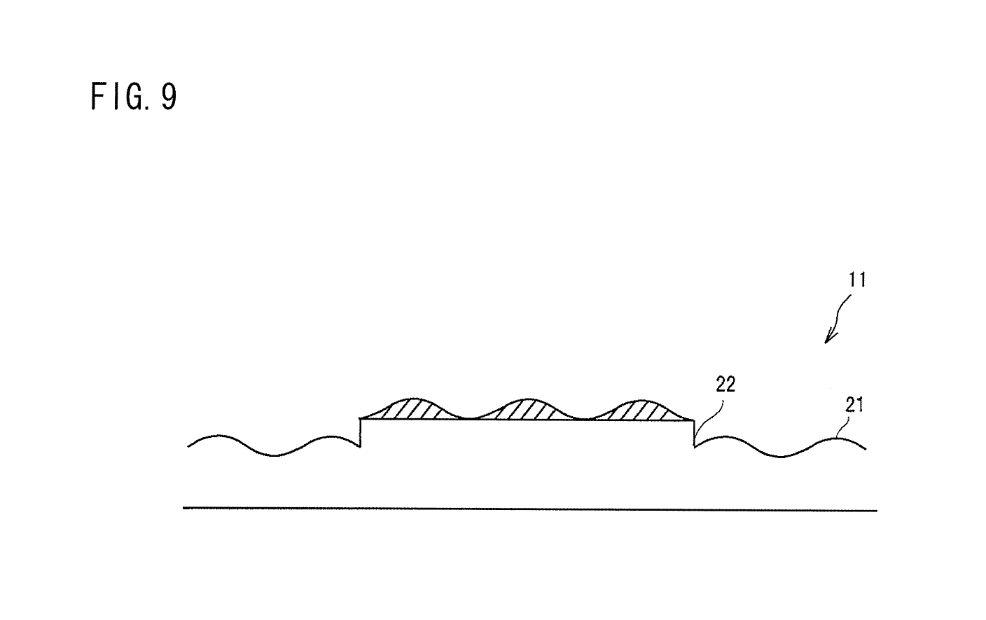

FIG. 9 is a cross-sectional view showing a method for working a surface of a heat dissipator in the electrical apparatus according to the first embodiment of the present invention.

With reference to FIG. 9, with respect to the electrical apparatus 201, surface working such as grinding and polishing is performed on the contact part 22, in the opposing part 21, which protrudes relative to the portion of the opposing part 21 other than the contact part 22, thereby increasing the degree of flatness of the surface of the contact part 22. As a result of this surface working, the level of the contact part 22 is lowered than that before the working. However, since the contact part 22 protrudes relative to the portion of the opposing part 21 other than the contact part 22 from the beginning, it is possible to bring the contact part 22 and the printed circuit board 1 into close contact with each other.

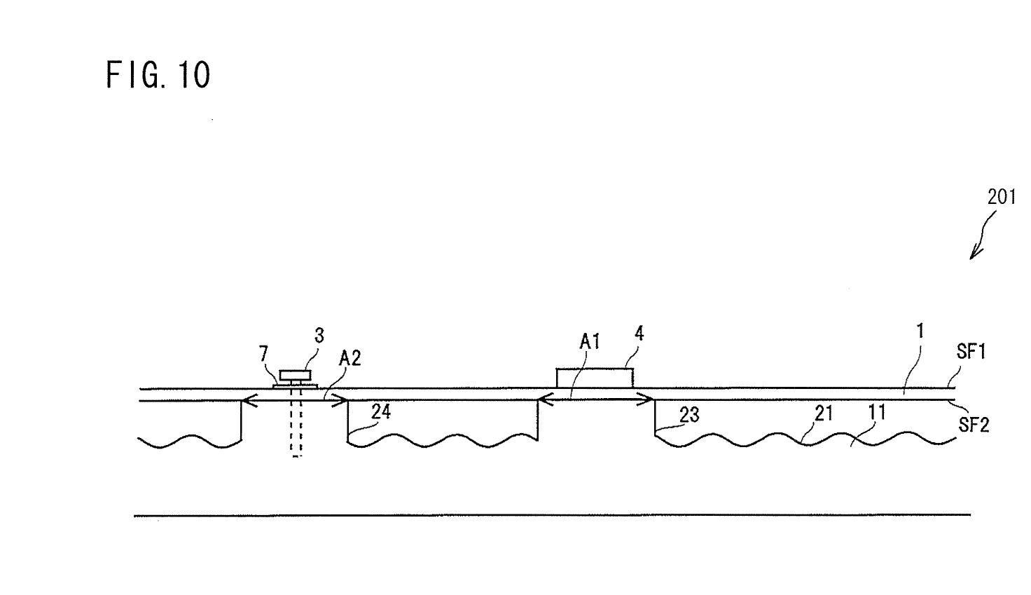

FIG. 10 is a cross-sectional view showing a mounting structure of a modification of the electrical apparatus according to the first embodiment of the present invention.

With reference to FIG. 10, the present invention is not limited to the structure provided with the contact part 22 which is brought into contact with both the region A1 and the region A2 and which protrudes relative to the portion of the opposing part 21 other than the contact part 22. The present invention may have a structure in which a contact part 23 which is brought into contact with the region A1 and a contact part 24 which is brought into contact with the region A2 may be separately provided.

Meanwhile, in the case of the structure in which heat dissipation is performed by bringing a board having a power device mounted thereon into contact with a heat dissipator and by fixing them together using a screw, if the evenness of the heat dissipator is low, the portions where the board is brought into contact with the heat dissipator are reduced, and thus, a sufficient heat dissipation effect is not obtained. On the other hand, in a heat dissipator, the greater the area having an increased evenness is, the greater the surface working costs become.

In contrast, in the electrical apparatus according to the first embodiment of the present invention, the fixing member 3 fixes the main surface SF2 of the printed circuit board 1 and the heat dissipator 11 together in such a manner as to be in contact with each other, by passing through the printed circuit board 1 from the main surface SF1 to the main surface SF2 to be inserted in the heat dissipator 11. In the opposing part 21 facing the printed circuit board 1, the opposing part 21 being on the surface of the heat dissipator 11, the contact part 22, which is brought into contact with the component region A1 of the main surface SF2 corresponding to the electrical component 4 and its surrounding region and which is brought into contact with the screw region A2 of the main surface SF2 corresponding to the fixing member 3 and its surrounding region, protrudes relative to the portion of the opposing part 21 other than the contact part 22. Further, the degree of flatness of the contact surface, in the contact part 22, that is brought into contact with the component region A1 and the screw region A2 is higher than the degree of flatness of the surface of the opposing part 21 other than the contact surface.

That is, in the first embodiment of the present invention, the heat dissipator 11 is produced through casting such that only the vicinity of the tapped hole and the vicinity of the power device protrude in the opposing part 21. Then, by increasing the degree of flatness only of the protruding contact part 22, the degree of contact between the printed circuit board 1 and the heat dissipator 11 is increased in the portion where the heat dissipation effect is especially enhanced.

This structure can realize both low surface working costs and a high heat dissipation effect. That is, it is possible to minimize the area having an increased degree of flatness, and to obtain a sufficient heat dissipation effect.

Therefore, in the electrical apparatus according to the first embodiment of the present invention, it is possible to improve the heat dissipation performance and to prevent increase of production costs.

Further, in the electrical apparatus according to the first embodiment of the present invention, the electrical component 4 is attached to the vicinity of the fixing member 3.

With this structure, the electrical component 4 can be arranged in a region having a high degree of contact with the heat dissipator 11, and heat generated from the electrical component 4 can be conducted to the heat dissipator 11 via the fixing member 3. Thus, the heat dissipation effect can further be enhanced.

Further, the electrical apparatus according to the first embodiment of the present invention is a radio communication device including, as the electrical component 4, an amplifier such as the power amplifier 85 for amplifying a radio signal.

With this structure, it is possible to appropriately take heat dissipation measures for the amplifier whose temperature is especially increased in the radio communication device.

Next, another embodiment of the present invention will be described with reference to the drawings. Note that the same or corresponding parts in the drawings are denoted by the same reference characters, and description thereof is not repeated.

### Second Embodiment

The present embodiment relates to an electrical apparatus in which the heat dissipation structure is changed compared with the electrical apparatus according to the first embodiment. The content other than that described below is the same as described with respect to the electrical apparatus according to the first embodiment.

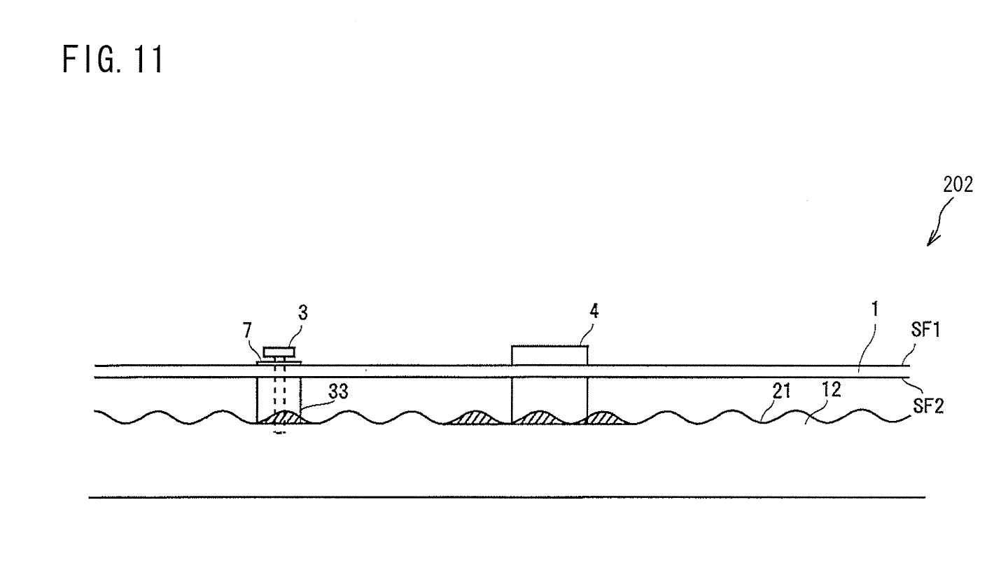

FIG. 11 is a cross-sectional view showing a mounting structure of an electrical apparatus according to a second embodiment of the present invention.

With reference to FIG. 11, compared with the electrical apparatus according to the first embodiment of the present invention, an electrical apparatus 202 further includes a heat dissipation member 33, and includes a heat dissipator 12 instead of the heat dissipator 11.

The printed circuit board 1 includes the main surface SF1 and the main surface SF2, and the electrical component 4 is attached to the printed circuit board 1.

The fixing member 3 fixes the printed circuit board 1 and the heat dissipator 12 in such a manner as to be spaced apart from each other, by passing through the printed circuit board 1 from the main surface SF1 to the main surface SF2 to be inserted in the heat dissipator 12. The fixing member 3 reaches the heat dissipator 12 by being inserted through the heat dissipation member 33 which is in close contact with the printed circuit board 1 and the heat dissipator 12 between the printed circuit board 1 and the heat dissipator 12.

The electrical component 4 projects from the main surface SF2 of the printed circuit board 1 and is in contact with the heat dissipator 12 at the tip of the projecting portion of the electrical component 4.

On a surface of the heat dissipator 12, the degree of flatness of the contact surface that is brought into contact with the electrical component 4 and the degree of flatness of the contact surface that is brought into contact with the heat dissipation member 33 are higher than the degree of flatness of the surface of the opposing part 21 other than these contact surfaces, the opposing part 21 facing the printed circuit board 1.

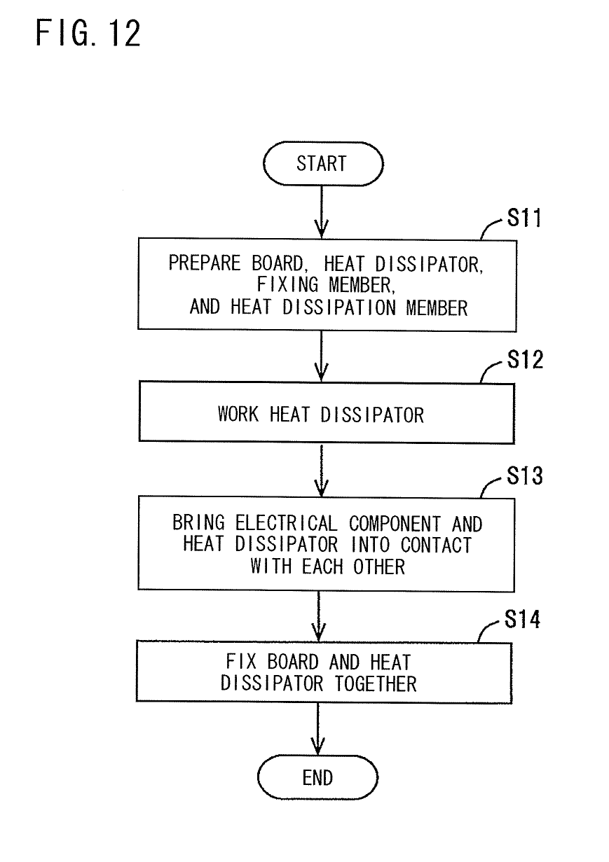

FIG. 12 is a flow chart defining the procedure for producing the electrical apparatus according to the second embodiment of the present invention.

With reference to FIG. 12, first, the printed circuit board 1 which includes the main surface SF1 and the main surface SF2 and to which the electrical component 4 is attached, the heat dissipator 12, the fixing member 3, and the heat dissipation member 33 are prepared (step S11).

Next, the heat dissipator 12 is worked such that, on the surface of the heat dissipator 12, the degree of flatness of the contact surface that is brought into contact with the electrical component 4 and the degree of flatness of the contact surface that is brought into contact with the heat dissipation member 33 become higher than the degree of flatness of the surface of the opposing part 21 other than these contact surfaces, the opposing part 21 facing the printed circuit board 1 (step S12).

Next, the electrical component 4 is caused to project from the main surface SF2 of the printed circuit board 1 to be brought into contact with the heat dissipator 12, at the tip of the projecting portion of the electrical component 4 (step S13).

Next, by passing the fixing member 3 through the printed circuit board 1 from the main surface SF1 to the main surface SF2 to be inserted in the heat dissipator 12 via the heat dissipation member 33, the printed circuit board 1 and the heat dissipator 12 are fixed in such a manner as to be spaced apart from each other (step S14).

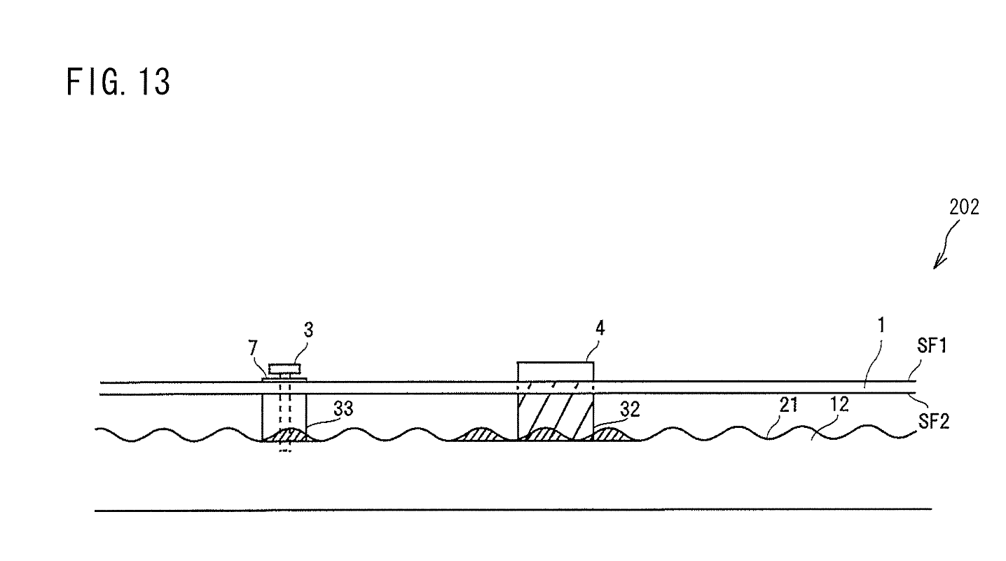

FIG. 13 is a cross-sectional view showing a mounting structure of a modification of the electrical apparatus according to the second embodiment of the present invention.

With reference to FIG. 13, the electrical apparatus 202 further includes a heat dissipation member 32. The present invention is not limited to the structure in which the electrical component 4 is directly brought into contact with the heat dissipator 12, as shown in FIG. 11. The present invention may have a structure in which the electrical component 4 is brought into contact with the heat dissipator 12 via the heat dissipation member 32 provided between the electrical component 4 and the heat dissipator 12.

In this case, on the surface of the heat dissipator 12, the degree of flatness of the contact surface that is brought into contact with the heat dissipation member 32 and the degree of flatness of the contact surface that is brought into contact with the heat dissipation member 33 are higher than the degree of flatness of the surface of the opposing part 21 other than these contact surfaces, the opposing part 21 facing the printed circuit board 1.

The other structures and operations are the same as those in the case of the electrical apparatus according to the first embodiment, and detailed description thereof is not repeated here.

As described above, in the electrical apparatus according to the second embodiment of the present invention, the fixing member 3 fixes the printed circuit board 1 and the heat dissipator 12 by passing through the printed circuit board 1 from the main surface SF1 to the main surface SF2 to be inserted in the heat dissipator 12. The electrical component 4 projects from the main surface SF2 of the printed circuit board 1 and is in contact with the heat dissipator 12 at the tip of the projecting portion of the electrical component 4. Alternatively, the electrical component 4 is contact with the heat dissipator 12 via the heat dissipation member 32 provided between the electrical component 4 and the heat dissipator 12. On the surface of the heat dissipator 12, the degree of flatness of the contact surface that is brought into contact with the electrical component 4 or the heat dissipation member 32 is higher than the degree of flatness of the surface of the opposing part 21 other than the contact surface, the opposing part 21 facing the printed circuit board 1.

That is, according to the second embodiment of the present invention, on the surface of the heat dissipator 12, by increasing the degree of flatness of the contact surface that is brought into contact with the electrical component 4 or the heat dissipation member 32, the degree of contact between the printed circuit board 1 and the heat dissipator 12 is increased in the portion where the heat dissipation effect is especially enhanced.

With this structure, as in the case of the electrical apparatus according to the first embodiment of the present invention, it is possible to improve the heat dissipation performance and to prevent increase of production costs.

Further, in the electrical apparatus according to the second embodiment of the present invention, the fixing member 3 reaches the heat dissipator 12 by being inserted through the heat dissipation member 33 which is in close contact with the printed circuit board 1 and the heat dissipator 12 between the printed circuit board 1 and the heat dissipator 12. In addition, on the surface of the heat dissipator 12, the degree of flatness of the contact surface that is brought into contact with the electrical component 4 or the heat dissipation member 32 and the degree of flatness of the contact surface that is brought into contact with the heat dissipation member 33 are higher than the degree of flatness of the surface of the opposing part 21 other than these contact surfaces.

As described above, by providing the heat dissipation member 33, and by increasing the degree of flatness of the contact surface, in the heat dissipator 12, that is brought into contact with the heat dissipation member 33, heat conduction from the electrical component 4 to the heat dissipator 12 can be promoted. Thus, the heat dissipation effect can further be enhanced.

Note that, in FIG. 13, it is sufficient that the heat dissipation member 32 is located between the heat dissipator 12 and the electrical component 4, and that one end of the heat dissipation member 32 is in contact with the heat dissipator 12. For example, the heat dissipation member 32 may be provided between the electrical component 4 projecting from the main surface SF2 of the printed circuit board 1 and the heat dissipator 12, the other end of the heat dissipation member 32 may be located inside the printed circuit board, or the other end of the heat dissipation member 32 may project from the main surface SF1.

Further, in the electrical apparatus according to the second embodiment of the present invention, heat from the electrical component 4 is conveyed directly or via the heat dissipation member 32 to the heat dissipator 12. Thus, instead of the heat dissipation member 33, a member having low heat dissipation ability may be provided.

Next, another embodiment of the present invention will be described with reference to the drawings. Note that the same or corresponding parts in the drawings are denoted by the same reference characters, and description thereof is not repeated.

### Third Embodiment

The present embodiment relates to an electrical apparatus in which the heat dissipation structure is changed compared with the electrical apparatus according to the first embodiment. The content other than that described below is the same as described with respect to the electrical apparatus according to the first embodiment.

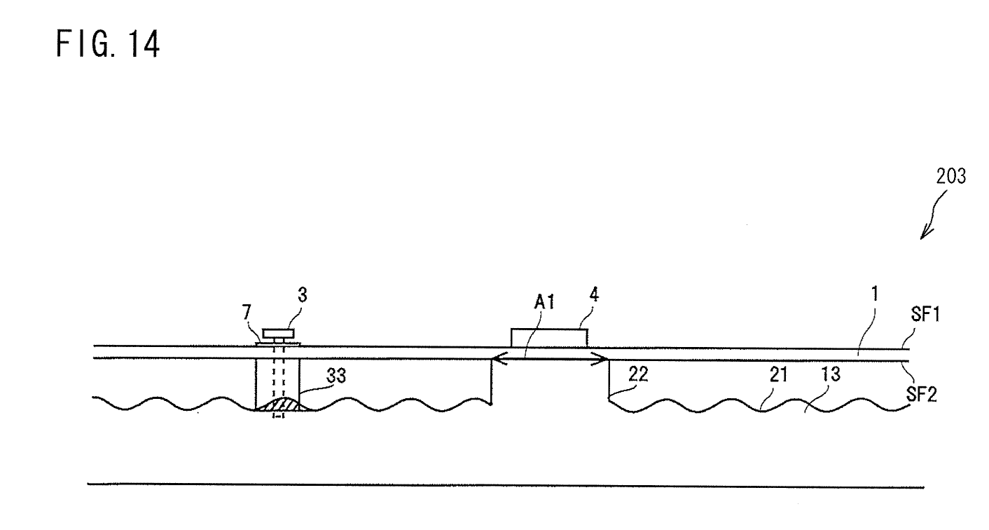

FIG. 14 is a cross-sectional view showing a mounting structure of an electrical apparatus according to a third embodiment of the present invention.

With reference to FIG. 14, compared with the electrical apparatus according to the first embodiment of the present invention, an electrical apparatus 203 further includes the heat dissipation member 33, and includes a heat dissipator 13 instead of the heat dissipator 11.

The printed circuit board 1 includes the main surface SF1 and the main surface SF2 and the electrical component 4 is attached to the main surface SF1.

The fixing member 3 fixes the main surface SF2 of the printed circuit board 1 and the heat dissipator 13 together in such a manner as to be in contact with each other, by passing through the printed circuit board 1 from the main surface SF1 to the main surface SF2 to be inserted in the heat dissipator 13. The fixing member 3 reaches the heat dissipator 13 by being inserted through the heat dissipation member 33 which is in close contact with the printed circuit board 1 and the heat dissipator 13 between the printed circuit board 1 and the heat dissipator 13.

In the opposing part 21 facing the printed circuit board 1, the opposing part 21 being on a surface of the heat dissipator 13, the contact part 22, which is brought into contact with the component region A1 of the main surface SF2 corresponding to the electrical component 4 and its surrounding region, protrudes relative to the portion of the opposing part 21 other than the contact part 22.

The degree of flatness of the contact surface, in the contact part 22, that is brought into contact with the component region A1 and the degree of flatness of the contact surface, in the heat dissipator 13, that is brought into contact with the heat dissipation member 33 are higher than the degree of flatness of the surface of the opposing part 21 other than these contact surfaces.

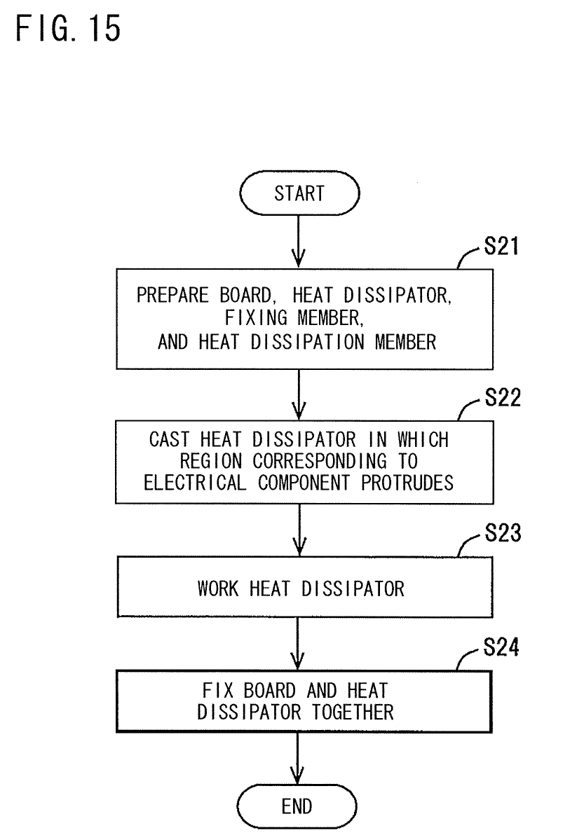

FIG. 15 is a flow chart defining the procedure for producing the electrical apparatus according to the third embodiment of the present invention.

With reference to FIG. 15, first, the printed circuit board 1 which includes the main surface SF1 and the main surface SF2 and in which the electrical component 4 is attached to the main surface SF1, the heat dissipator 13, the fixing member 3, and the heat dissipation member 33 are prepared (step S21).

Next, the heat dissipator 13 is cast in which, in the opposing part 21 facing the printed circuit board 1, the contact part 22, which is brought into contact with the component region A1 of the main surface SF2 corresponding to the electrical component 4 and its surrounding region, protrudes relative to the portion of the opposing part 21 other than the contact part 22 (step S22).

Next, the heat dissipator 13 is worked such that the degree of flatness of the contact surface, in the contact part 22, that is brought into contact with the component region Al, and the degree of flatness of the contact surface, in the heat dissipator 13, that is brought into contact with the heat dissipation member 33 are higher than the degree of flatness of the surface of the opposing part 21 other than these contact surfaces (step S23).

Next, by passing the fixing member 3 through the printed circuit board 1 from the main surface SF1 to the main surface SF2 to be inserted in the heat dissipator 13 via the heat dissipation member 33, the main surface SF2 of the printed circuit board 1 and the heat dissipator 13 are fixed together in such as a manner as to be in contact with each other (step S24).

The other structures and operations are the same as those in the case of the electrical apparatus according to the first embodiment, and detailed description thereof is not repeated here.

As described above, in the electrical apparatus according to the third embodiment of the present invention, the fixing member 3 fixes the main surface SF2 of the printed circuit board 1 and the heat dissipator 13 together, by passing through the printed circuit board 1 from the main surface SF1 to the main surface SF2 to be inserted in the heat dissipator 13. In the opposing part 21 facing the printed circuit board 1, the opposing part 21 being on the surface of the heat dissipator 13, the contact part 22, which is brought into contact with the component region A1 of the main surface SF2 corresponding to the electrical component 4 and its surrounding region, protrudes relative to the portion of the opposing part 21 other than the contact part 22. In addition, the degree of flatness of the contact surface, in the contact part 22, that is brought into contact with the component region A1 is higher than the degree of flatness of the surface of the opposing part 21 other than the contact surface.

That is, in the third embodiment of the present invention, the heat dissipator 13 is produced through casting such that only the vicinity of the power device protrudes in the opposing part 21. Then, by increasing the degree of flatness of the protruding contact part 22, the degree of contact between the printed circuit board 1 and the heat dissipator 13 is increased in the portion where the heat dissipation effect is especially enhanced.

Further, in the electrical apparatus according to the third embodiment of the present invention, the fixing member 3 reaches the heat dissipator 13 by being inserted through the heat dissipation member 33 which is in close contact with the printed circuit board 1 and the heat dissipator 13 between the printed circuit board 1 and the heat dissipator 13. In addition, the degree of flatness of the contact surface, in the contact part, that is brought into contact with the component region A1, and the degree of flatness of the contact surface, in the heat dissipator 13, that is brought into contact with the heat dissipation member 33 are higher than the degree of flatness of the surface of the opposing part 21 other than these contact surfaces.

As described above, by providing the heat dissipation member 33, and by increasing the degree of flatness of the contact surface, in the heat dissipator 13, that is brought into contact with the heat dissipation member 33, heat conduction from the electrical component 4 to the heat dissipator 13 is promoted. Thus, the heat dissipation effect can be enhanced.

Therefore, in the electrical apparatus according to the third embodiment of the present invention, as in the case of the electrical apparatus according to the first embodiment of the present invention, it is possible to improve the heat dissipation performance and to prevent increase of production costs.

Next, another embodiment of the present invention will be described with reference to the drawings. Note that the same or corresponding parts in the drawings are denoted by the same reference characters, and description thereof is not repeated.

### Fourth Embodiment

The present embodiment relates to an electrical apparatus in which the heat dissipation structure is changed compared with the electrical apparatus according to the first embodiment. The content other than that described below is the same as described with respect to the electrical apparatus according to the first embodiment.

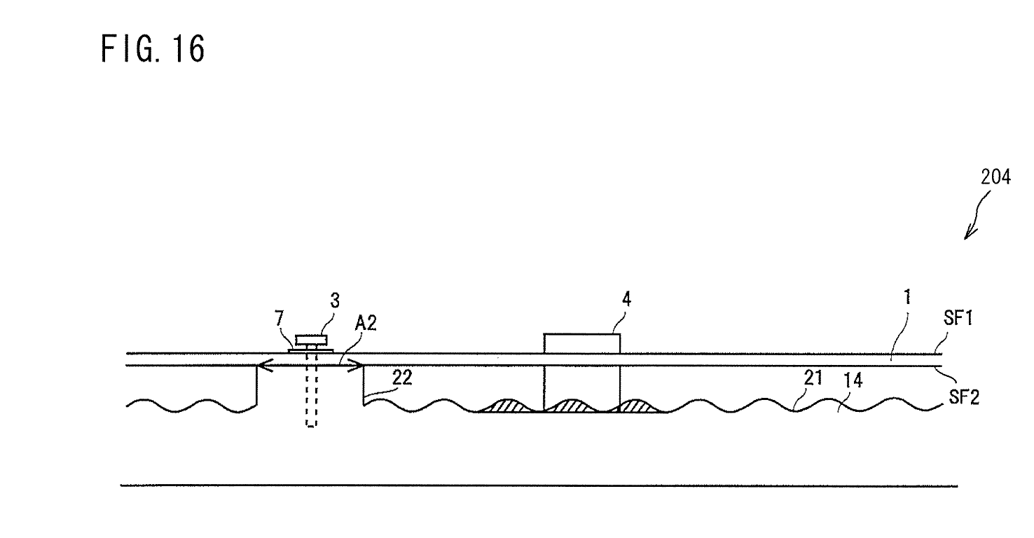

FIG. 16 is a cross-sectional view showing a mounting structure of an electrical apparatus according to a fourth embodiment of the present invention.

With reference to FIG. 16, an electrical apparatus 204 includes a heat dissipator 14 instead of the heat dissipator 11, compared with the electrical apparatus according to the first embodiment of the present invention.

The printed circuit board 1 includes the main surface SF1 and the main surface SF2, and the electrical component 4 is attached to the printed circuit board 1.

The fixing member 3 fixes the main surface SF2 of the printed circuit board 1 and the heat dissipator 14 together in such a manner as to be in contact with each other, by passing through the printed circuit board 1 from the main surface SF1 to the main surface SF2 to be inserted in the heat dissipator 14.

In the opposing part 21 facing the printed circuit board 1, the opposing part 21 being on a surface of the heat dissipator 14, the contact part 22, which is brought into contact with the screw region A2 of the main surface SF2 corresponding to the fixing member 3 and its surrounding region, protrudes relative to the portion of the opposing part 21 other than the contact part 22.

The electrical component 4 projects from the main surface SF2 of the printed circuit board 1, and is in contact with the heat dissipator 14 at the tip of the projecting portion of the electrical component 4. Note that, as in the case of the modification of the electrical apparatus according to the second embodiment of the present invention, the electrical component 4 and the heat dissipator 14 may be brought into contact with each other via the heat dissipation member 32 provided between the electrical component 4 and the heat dissipator 14.

The degree of flatness of the contact surface, in the contact part 22, that is brought into contact with the screw region A2 and the degree of flatness of the contact surface, in the opposing part 21, that is brought into contact with the electrical component 4 or the heat dissipation member 32 are higher than the degree of flatness of the surface of the opposing part 21 other than these contact surfaces.

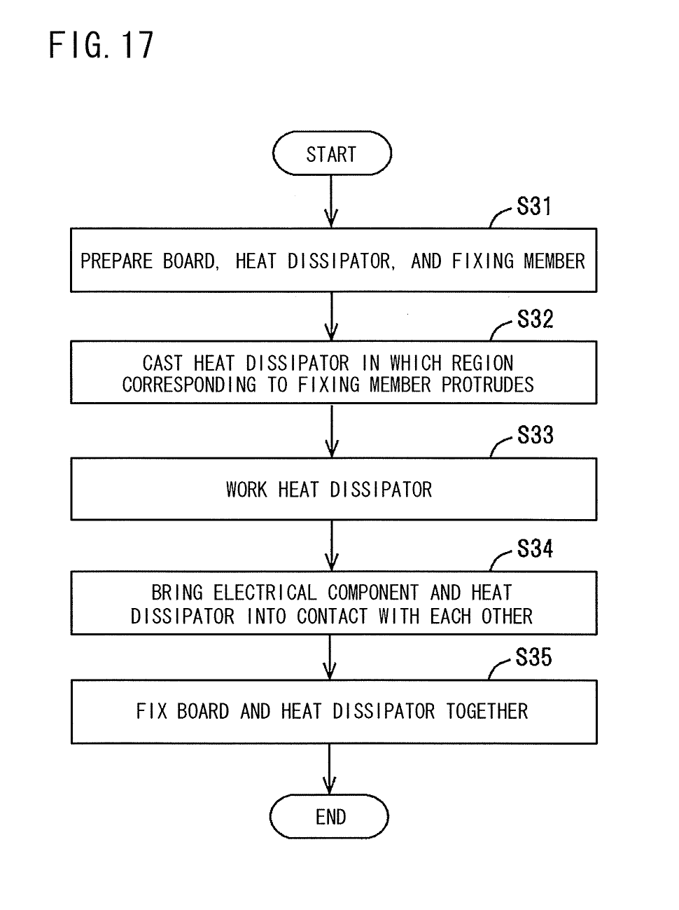

FIG. 17 is a flow chart defining the procedure for producing the electrical apparatus according to the fourth embodiment of the present invention.

With reference to FIG. 17, first, the printed circuit board 1 which includes the main surface SF1 and the main surface SF2 and to which the electrical component 4 is attached, the heat dissipator 14, the fixing member 3 to be passed through the printed circuit board 1 from the main surface SF1 to the main surface SF2 are prepared (step S31).

Next, the heat dissipator 14 is cast in which, in the opposing part 21 facing the printed circuit board 1, the contact part 22, which is brought into contact with the screw region A2 of the main surface SF2 corresponding to the fixing member 3 and its surrounding region, protrudes relative to the portion of the opposing part 21 other than the contact part 22 (step S32).

Next, the heat dissipator 14 is worked such that the degree of flatness of the contact surface, in the contact part 22, that is brought into contact with the screw region A2, and the degree of flatness of the contact surface, in the opposing part 21, that is brought into contact with the electrical component 4 or the heat dissipation member 32 are higher than the degree of flatness of the surface of the opposing part 21 other than these contact surfaces (step S33).

Next, the electrical component 4 is caused to project from the main surface SF2 of the printed circuit board 1 to be brought into contact with the heat dissipator 14, at the tip of the projecting portion of the electrical component 4, or the electrical component 4 is brought into contact with the heat dissipator 14, via the heat dissipation member 32 provided between the electrical component 4 and the heat dissipator 14 (step S34).

Next, by passing the fixing member 3 through the printed circuit board 1 from the main surface SF1 to the main surface SF2 to be inserted in the heat dissipator 14, the main surface SF2 of the printed circuit board 1 and the electrical component 4, and the heat dissipator 14 are fixed together in such a manner as to be contact with each other (step S35).

The other structures and operations are the same as those in the case of the electrical apparatus according to the first embodiment, and detailed description thereof is not repeated here.

As described above, in the electrical apparatus according to the fourth embodiment of the present invention, the fixing member 3 fixes the main surface SF2 of the printed circuit board 1 and the heat dissipator 14 together in such a manner as to be in contact with each other, by passing through the printed circuit board 1 from the main surface SF1 to the main surface SF2 to be inserted in the heat dissipator 14. In the opposing part 21 facing the printed circuit board 1, the opposing part 21 being on the surface of the heat dissipator 14, the contact part 22, which is brought into contact with the screw region A2 of the main surface SF2 corresponding to the fixing member 3 and its surrounding region, protrudes relative to the portion of the opposing part 21 other than the contact part 22. The electrical component 4 projects from the main surface SF2 of the printed circuit board 1, and is in contact with the heat dissipator 14 at the tip of the projecting portion of the electrical component 4 or is in contact with the heat dissipator 14 via the heat dissipation member 32 provided between the electrical component 4 and the heat dissipator 14. Further, the degree of flatness of the contact surface, in the contact part 22, that is brought into contact with the screw region A2, and the degree of flatness of the contact surface, in the opposing part 21, that is brought into contact with the electrical component 4 or the heat dissipation member 32 are higher than the degree of flatness of the surface of the opposing part 21 other than these contact surfaces.

That is, in the fourth embodiment of the present invention, the heat dissipator 14 is produced through casting such that only the vicinity of the tapped hole protrudes in the opposing part 21. Then, by increasing, on the surface of the heat dissipator 14, the degree of flatness only of the contact surface of the protruding contact part 22 and the contact surface that is brought into contact with the electrical component 4 or the heat dissipation member 32, the degree of contact between the printed circuit board 1 and the heat dissipator 14 is increased in the portion where the heat dissipation effect is especially enhanced.

With this structure, as in the case of the electrical apparatus according to the first embodiment of the present invention, it is possible to improve the heat dissipation performance and to prevent increase of production costs.

The above embodiments are to be considered in all respects as illustrative and not restrictive. The scope of the present invention is indicated by the appended claims rather than by the foregoing description, and all changes that come within the meaning and range of equivalency of the claims are therefore intended to be embraced therein.

### DESCRIPTION OF THE REFERENCE CHARACTERS

1 printed circuit board
2 heat dissipator
3 fixing member
4 electrical component
7 washer
11, 12, 13, 14 heat dissipator
21 opposing part
22 contact part
32, 33 heat dissipation member
71 radio transmission section
72 radio reception section
81 signal processing section
82 digital/analog converter (DAC)
83 modulator
84 driver amplifier
85 power amplifier
86 transmission and reception filter
87 oscillator
89, 90 reception amplifier
91 mixer
92 BPF
93 analog/digital converter (ADC)
94 oscillator
101 remote radio head
102 body device
103 antenna
104 antenna pole
201, 202, 203, 204 electrical apparatus
A1 component region
A2 screw region
SF1, SF2 main surface

1. An electrical apparatus comprising:
a board which includes a first main surface and a second main surface and in which an electrical component is attached to the first main surface;
a heat dissipator; and
a fixing member which fixes the second main surface of the board and the heat dissipator together in such a manner as to be in contact with each other, by passing through the board from the first main surface to the second main surface to be inserted in the heat dissipator, wherein
in an opposing part facing the board, the opposing part being on a surface of the heat dissipator, a contact part which is brought into contact with a first region of the second main surface corresponding to the electrical component and a surrounding region of the electrical component and which is brought into contact with a second region of the second main surface corresponding to the fixing member and a surrounding region of the fixing member protrudes relative to a portion of the opposing part other than the contact part, and
the degree of flatness of a contact surface, in the contact part, that is brought into contact with the first region and the second region is higher than the degree of flatness of a surface of the opposing part other than the contact surface.

2. An electrical apparatus comprising:
a board which includes a first main surface and a second main surface and to which an electrical component is attached;
a heat dissipator, and
a fixing member which fixes the board and the heat dissipator together by passing through the board from the first main surface to the second main surface to be inserted in the heat dissipator, wherein
the electrical component projects from the second main surface of the board, and is in contact with the heat dissipator at a tip of a projecting portion of the electrical component or in contact with the heat dissipator via a first heat dissipation member provided between the electrical component and the heat dissipator, and
on the surface of the heat dissipator, the degree of flatness of a contact surface that is brought into contact with the electrical component or the first heat dissipation member is higher than the degree of flatness of a surface of an opposing part other than the contact surface, the opposing part facing the board.

3. The electrical apparatus according to claim 2, wherein
the fixing member reaches the heat dissipator by being inserted through a second heat dissipation member which is in close contact with the board and the heat dissipator between the board and the heat dissipator, and
on the surface of the heat dissipator, the degree of flatness of the contact surface that is brought into contact with the electrical component or the first heat dissipation member and the degree of flatness of a contact surface that is brought into contact with the second heat dissipation member are higher than the degree of flatness of a surface of the opposing part other than these contact surfaces.

4. The electrical apparatus according to claim 2, wherein
in the opposing part, a contact part which is brought into contact with a member region of the second main surface corresponding to the fixing member and a surrounding region of the fixing member protrudes relative to a portion of the opposing part other than the contact part, and
the degree of flatness of the contact surface, on the surface of the heat dissipator, that is brought into contact with the electrical component or the first heat dissipation member, and the degree of flatness of a contact surface, in the contact part, that is brought into contact with the member region are higher than the degree of flatness of a surface of the opposing part other than these contact surfaces.

5. An electrical apparatus comprising:
a board which includes a first main surface and a second main surface and in which an electrical component is attached to the first main surface;
a heat dissipator; and
a fixing member which fixes the second main surface of the board and the heat dissipator together in such a manner as to be in contact with each other, by passing through the board from the first main surface to the second main surface to be inserted in the heat dissipator, wherein
in an opposing part facing the board, the opposing part being on a surface of the heat dissipator, a contact part which is brought into contact with a component region of the second main surface corresponding to the electrical component and a surrounding region of the electrical component protrudes relative to a portion of the opposing part other than the contact part, and
the fixing member reaches the heat dissipator by being inserted through a heat dissipation member which is in close contact with the board and the heat dissipator between the board and the heat dissipator, and
the degree of flatness of a contact surface, in the contact part, that is brought into contact with the component region, and the degree of flatness of a contact surface, in the heat dissipator, that is brought into contact with the heat dissipation member are higher than the degree of flatness of a surface of the opposing part other than these contact surfaces.

6. The electrical apparatus according to any one of claims 1, wherein
the electrical component is attached to a vicinity of the fixing member.

7. The electrical apparatus according to claim 1, wherein
the electrical apparatus is a radio communication device which includes an amplifier for amplifying a radio signal, as the electrical component.

8. A method for producing an electrical apparatus, the method comprising:
a step of preparing a board which includes a first main surface and a second main surface and in which an electrical component is attached to the first main surface, and a fixing member to be passed through the board from the first main surface to the second main surface;
a step of casting a heat dissipator in which, in an opposing part facing the board, the opposing part being on a surface of the heat dissipator, a contact part which is brought into contact with a first region of the second main surface corresponding to the electrical component and a surrounding region of the electrical component and which is brought into contact with a second region of the second main surface corresponding to the fixing member and a surrounding region of the fixing member protrudes relative to a portion of the opposing part other than the contact part;
a step of working the heat dissipator such that the degree of flatness of a contact surface, in the contact part, that is brought into contact with the first region and the second region is higher than the degree of flatness of a surface of the opposing part other than the contact surface; and
a step of fixing the second main surface of the board and the heat dissipator together in such a manner as to be in contact with each other, by passing the fixing member through the board from the first main surface to the second main surface to be inserted in the heat dissipator.

9. A method for producing an electrical apparatus, the method comprising:
a step of preparing a board which includes a first main surface and a second main surface and to which an electrical component is attached, and a fixing member to be passed through the board from the first main surface to the second main surface;
a step of causing the electrical component to project from the second main surface of the board to be brought into contact with a heat dissipator at a tip of a projecting portion of the electrical component, or bringing the electrical component into contact with the heat dissipator via a heat dissipation member provided between the electrical component and the heat dissipator;
a step of fixing the second main surface of the board and the electrical component, and the heat dissipator together, by passing the fixing member through the board from the first main surface to the second main surface to be inserted in the heat dissipator; and
a step of working, before the step of bringing the electrical component into contact and the step of fixing the electrical component using the fixing member, the heat dissipator such that, in an opposing part facing the board, the opposing part being on a surface of the heat dissipator, the degree of flatness of a contact surface that is brought into contact with the electrical component or the heat dissipation member is higher than the degree of flatness of a surface of the opposing part other than the contact surface.

10. The electrical apparatus according to any one of claims 2, wherein the electrical component is attached to a vicinity of the fixing member.

11. The electrical apparatus according to any one of claims 5, wherein
the electrical component is attached to a vicinity of the fixing member.

12. The electrical apparatus according to claim 2, wherein
the electrical apparatus is a radio communication device which includes an amplifier for amplifying a radio signal, as the electrical component.

13. The electrical apparatus according to claim 5, wherein
the electrical apparatus is a radio communication device which includes an amplifier for amplifying a radio signal, as the electrical component.
